(19) United States
(12) Patent Application Publication
(10) Pub. No.: US 2026/0143997 A1
(43) Pub. Date: May 21, 2026

(54) DOOR BODY

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); CHENG-WU CHUNG, New Taipei City (TW); JING-JIE SOU, New Taipei City (TW); YU-HSIEN LEE, New Taipei City (TW); TZU-HSIANG WEI, New Taipei City (TW)

(73) Assignee: GUDENG PRECISION INDUSTRIAL CO., LTD., New Taipei City (TW)

(21) Appl. No.: 19/390,705

(22) Filed: Nov. 17, 2025

Related U.S. Application Data
(60) Provisional application No. 63/722,082, filed on Nov. 19, 2024.

(51) Int. Cl. H01L 21/673

(52) U.S. Cl. CPC H10P 72/1914; H10P 72/1916; H10P 72/1922

(57) ABSTRACT

A door body is applicable to a semiconductor container and is configured to be combined with the semiconductor container. The door body includes a latch apparatus and an operation indicating member. The latch apparatus is disposed on the door body and is configured to lock the door body to or unlock the door body from the semiconductor container. The operation indicating member is disposed on the latch apparatus and is configured to identify an operation status. Consequently, the door body can be protected during locking or unlocking process of the door body, to avoid damage to the door body or the latch apparatus thereon. Preferably, picking portions are configured on two sides of the door body, so that a latch can be matched with the picking portions for use, thereby further enhancing protection of the door body and the semiconductor container to which the door body is applied.

### CROSS-REFERENCE TO RELATED APPLICATION

This non-provisional application claims priority under 35 U.S.C. § 119(e) on U.S. provisional Patent Application No(s). 63/722,082 filed on Nov. 19, 2024, the entire contents of which are hereby incorporated by reference.

### BACKGROUND OF THE INVENTION

### 1. Field of the Invention

The present disclosure relates to a door body, and in particular, to a door body applicable to a semiconductor container that can identify an operation status when the door body is locked or unlocked and has an anti-damage design.

### 2. Description of the Related Art

Containers are usually required for accommodating, protecting, carrying, or transporting electronic component-related products in the semiconductor industry, such as circuit boards, wafers, and glass. The containers carrying the electronic component-related products or semiconductor manufacturing process-related components require well-designed protective measures to prevent damage to the semiconductor components stored and carried therein.

To protect the components stored inside the semiconductor container, a latch mechanism is disposed on a door body, to prevent the semiconductor components from falling out of the semiconductor container during transportation. When the semiconductor container is in each process station during a manufacturing process, the door body of the container needs to be opened and closed frequently to allow each process station to take the semiconductor components out and place the semiconductor components in and to perform various manufacturing processes. However, conventionally, during opening and closing of the door body of the semiconductor container, a door body fixing mechanism often receives an excessively concentrated force, resulting in damage to the door body or the fixing mechanism. For example, when a key is used to drive to open a latch fixing mechanism disposed on the door body, conventionally, after a latched state is released by using the key, the key and the door body are jointly pulled to open the door body. However, when the key is used to pull to open the door body, most of the weight of the door body is supported by the key and the latch fixing mechanism. Therefore, this can easily cause deformation and damage to internal components of the door body and/or the latch fixing mechanism due to compression by force.

In addition, conventionally, during opening and closing of the latch fixing mechanism of the door body, damage is often caused due to an excessive working stroke or an improper operation of the door body fixing mechanism. Using a latch fixing mechanism having an operating member and a latch member as an example, the operating member, for example, a cam, is used to drive the latch member to move linearly. However, conventional latch fixing mechanism may be excessively unlocked or sustained improper force when a user uses the key to operate the operating member. Consequently, a working stroke of parts of the latch fixing mechanism is excessive, resulting in deformation or damage to the parts. As a result, the latch fixing mechanism of the door body fails, or other parts are damaged.

Furthermore, conventional semiconductor container also has a problem that a fixing status of the door body cannot be determined, for example, it cannot be determined that the latch fixing mechanism opened or closed by using the key is in a locked or unlocked state. Consequently, the door body tends to be fixed poorly or the door body further tends to fall, causing damage to the semiconductor container or the door body and endangering the semiconductor components stored and carried in the semiconductor container.

### BRIEF SUMMARY OF THE INVENTION

The present disclosure provides a door body on a semiconductor container. It is important that the door body can identify an operation status and prevent damage to the door body during operation of opening, closing, locking or unlocking the door body, and resolve the problem of damage to the door body due to an excessively concentrated force applied to a latch when picking the door body, thereby extending a service life of the semiconductor container and preventing damage to a semiconductor component stored inside due to damage to the door body of the semiconductor container, to improve preservation quality of the semiconductor component.

In view of this, when the door body of the container is opened or closed, the door body provided in the present disclosure can prevent the weight of the door body of the container from being concentrated at a fixed latch apparatus, avoid an excessive working stroke of a latch fixing mechanism, and provide direct and clear identification of the operation status of the door body being locked or unlocked, to reduce damage to the door body and the internal parts of the door body and improve the service life of the semiconductor container and the door body and the preservation quality of the semiconductor component.

An aspect of the present disclosure provides a door body, applicable to a semiconductor container. The door body includes: a latch apparatus, disposed on the door body, where the latch apparatus is configured to lock the door body to or unlock the door body from the semiconductor container; and an operation indicating member, disposed on the latch apparatus, where the operation indicating member is configured to identify an operation status.

In an embodiment, the operation indicating member is in a first state according to a locking operation performed by the latch apparatus, and is in a second state according to an unlocking operation.

In an embodiment, the operation indicating member has different colors to identify the first state or the second state.

In an embodiment, the latch apparatus includes an unlocking limit member and a locking limit member, the latch apparatus is in the first state when the locking operation is performed on the locking limit member, and the latch apparatus is in the second state when the unlocking operation is performed on the unlocking limit member.

In an embodiment, the latch apparatus further includes: an operating member, at least one latch member coupled to the operating member, and an unlocking portion and a locking portion that are located on the operating member, where operation of the operating member drives the latch member to move linearly and synchronously drives the unlocking portion and the locking portion, the unlocking portion is paired and moved to the unlocking limit member to perform unlocking limiting, and the locking portion is paired and moved to the locking limit member to perform locking limiting.

In an embodiment, the door body further includes a door main body and a sealing plate, the latch apparatus is disposed in an accommodating space defined by the door main body and the sealing plate, and the sealing plate has a hole for observing the operation indicating member.

In an embodiment, the door body further includes at least two picking portions, respectively configured on two sides adjacent to the door body, where the picking portions are provided for picking the door body.

Another aspect of the present disclosure provides a door body, applicable to a semiconductor container. The door body is configured to be combined with the semiconductor container. The door body includes: a latch apparatus, disposed on the door body, where the latch apparatus is configured to lock the door body to or unlock the door body from a container body; an operation indicating member, disposed on the latch apparatus, where the operation indicating member is configured to identify an operation status; and at least two picking portions, respectively configured on two sides adjacent to the door body, where the picking portions are provided for picking the door body.

In an embodiment, the picking portion is a picking groove.

In an embodiment, the picking groove includes a placing groove and a holding flange.

In an embodiment, the picking portion is a picking handle.

According to the door body of the present disclosure, through arrangement of the latch apparatus and the operation indicating member, in a process of opening and closing the door body and locking and unlocking the latch apparatus, damage caused to a fixing mechanism such as the door body or the latch apparatus due to an excessively concentrated force applied to the door body of the container or the latch apparatus on the door body is avoided. In addition, in a process of locking the door body of the container, damage to the door body of the container or the latch apparatus on the door body caused by an excessively large working stroke can be avoided, so that an operation status of locking or unlocking the door body can be clearly identified at any time, and whether the door body of the container is locked to a container body can be determined, to avoid damage due to incorrect force applied to the door body of the container or damage caused by separating or falling of the door body of the container.

### BRIEF DESCRIPTION OF THE DRAWINGS

FIG. 1 is a three-dimensional schematic exploded view of a semiconductor container according to an embodiment of the present disclosure.

FIG. 2A and FIG. 2B are schematic exploded views of a part of a door body according to an embodiment of the present disclosure.

FIG. 3A and FIG. 3B are three-dimensional schematic diagrams of a door body and an operation indicating member according to an embodiment of the present disclosure.

FIG. 4A and FIG. 4B are schematic diagrams of a locking limit operation according to an embodiment of the present disclosure.

FIG. 5A and FIG. 5B are schematic diagrams of an unlocking limit operation according to an embodiment of the present disclosure.

FIG. 6 is a three-dimensional schematic diagram of a door body according to an embodiment of the present disclosure.

FIG. 7 is a schematic structural diagram of a picking portion of a door body according to an embodiment of the present disclosure.

### DETAILED DESCRIPTION OF THE INVENTION

To describe the technical content of the present disclosure in detail, the descriptions are further provided below with reference to implementations and drawings. A person skilled in the art can understand the objectives, features, and effects of the present disclosure from the content disclosed in this specification. It should be noted that the present disclosure may be implemented or applied through other different specific embodiments, and various details in this specification may also be modified and changed based on different viewpoints and applications without departing from the spirit of the present disclosure. The relevant technical content of the present disclosure is further described in detail through the following implementations, but the disclosed content is not intended to limit the scope of the claims of the present application.

It should be noted that, in the content of this specification, terms such as “first”, “second”, and “third” are used to distinguish between elements, rather than to limit the elements or indicate a specific order of the elements. In addition, in the content of this specification, when no specific quantity is specified, the article “a” refers to one element or more than one element. Moreover, the steps described in this application may be performed sequentially, in a reverse sequence, or by appropriately changing or skipping a sequence during control processing.

In addition, the term “coupled” described in this specification may be represented as “directly connected” and/or “indirectly connected”. Specifically, “a first element is configured to be coupled with a second element” may be represented as “the first element is configured to be directly connected to the second element” and/or “the first element is configured to be indirectly connected to the second element”. In addition, it should further be noted that, “upper”, “lower”, “left”, “right”, “front”, “rear”, and the like described in this specification are merely exemplary descriptions of relative directions, a reference direction may be randomly changed, and is not limited to an absolute direction.

For ease of understanding, embodiments, schematic diagrams, and the like of a door body of a semiconductor container of the present disclosure are described below.

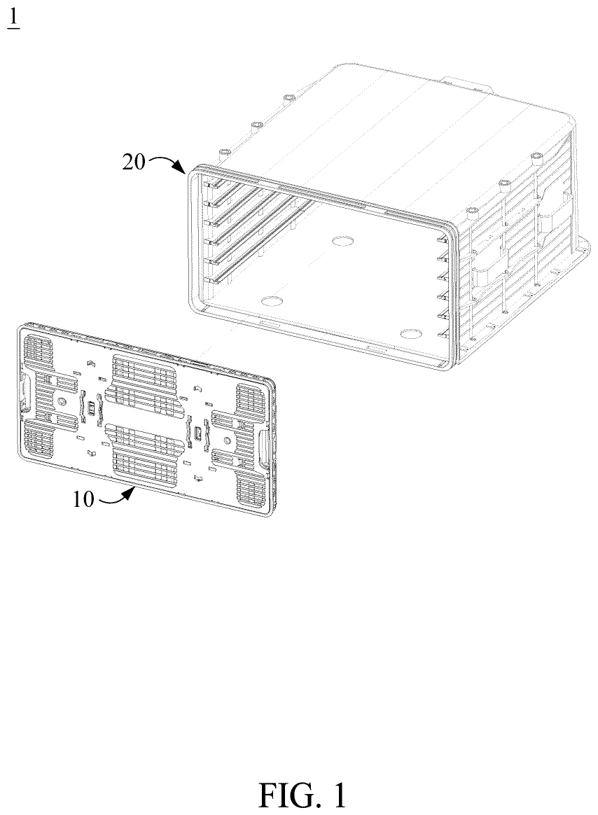

FIG. 1 is a three-dimensional schematic exploded view of a semiconductor container according to an embodiment of the present disclosure. An aspect of the present disclosure provides a door body 10, applicable to a semiconductor container 1. The semiconductor container 1 is, for example, a wafer carrier pod, a mask carrier pod, a carrier board carrier pod or another component carrier transport equipment, a processing apparatus, or the like in a semiconductor manufacturing process, but is not limited thereto. The semiconductor container 1 has a container body 20, and the door body 10 is configured to be combined with the container body 20 to form an accommodating space of the container, to accommodate various elements in the semiconductor manufacturing process.

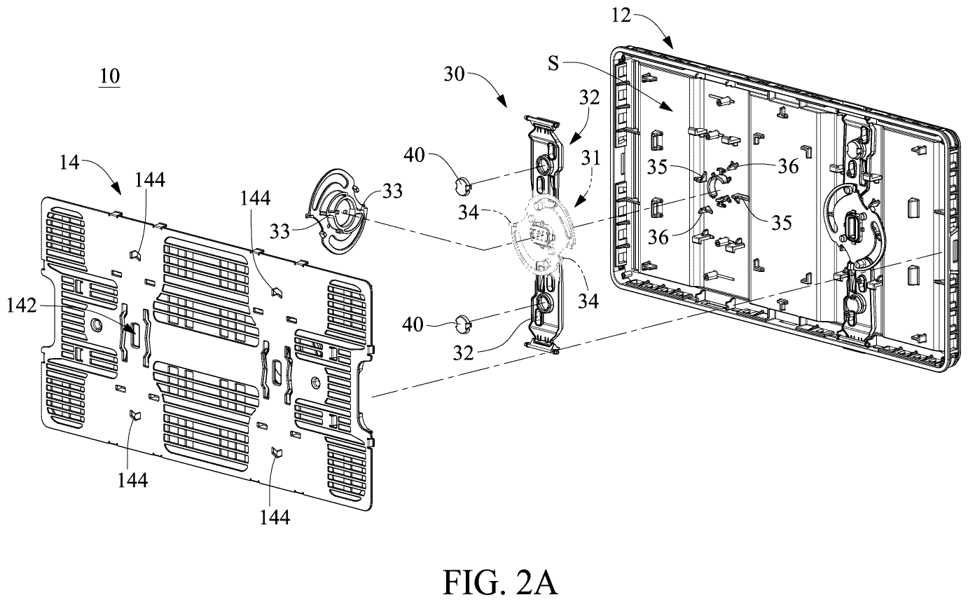

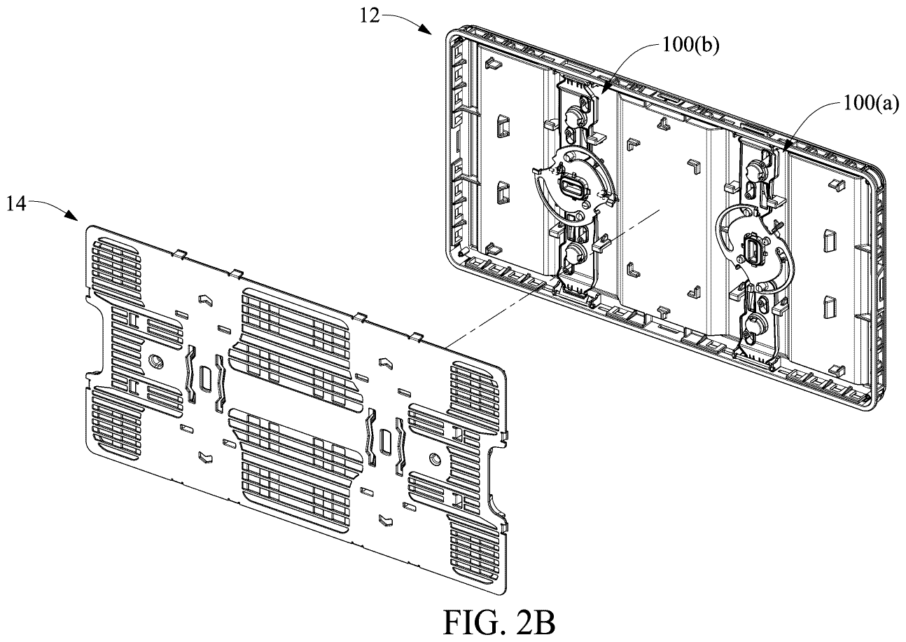

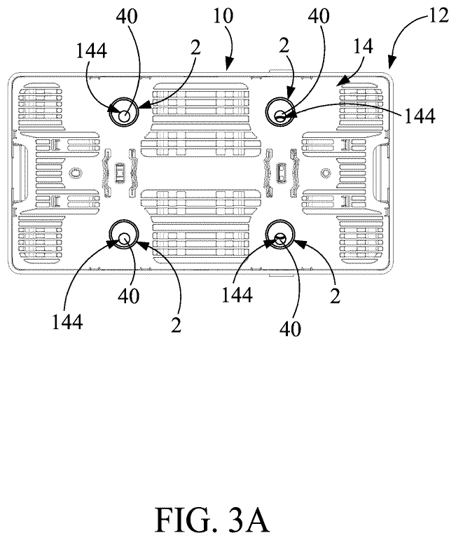

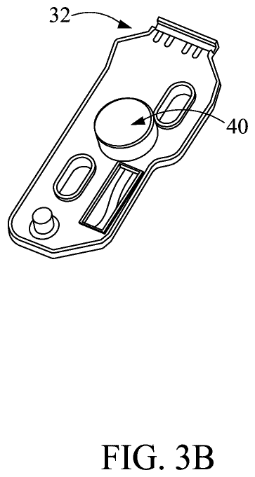

Refer to FIG. 1, FIG. 2A, FIG. 2B, FIG. 3A, and FIG. 3B together. FIG. 2A and FIG. 2B are schematic exploded views of a part of a door body according to an embodiment of the present disclosure; and FIG. 3A and FIG. 3B are three-dimensional schematic diagrams of a door body and an operation indicating member according to an embodiment of the present disclosure. An aspect of the present disclosure provides a door body 10. The door body 10 includes a latch apparatus 30 and an operation indicating member 40 that may be used as a protection apparatus 2 of the door body 10.

The latch apparatus 30 is disposed on the door body 10, and the latch apparatus 30 is configured to selectively lock the door body 10 to the container body 20, that is, the latch apparatus 30 is configured to lock the door body 10 to or unlock the door body 10 from the container body 20. The operation indicating member 40 is disposed on the latch apparatus 30, where the operation indicating member 40 is configured to identify an operation status. When the latch apparatus 30 performs a locking operation to lock the door body 10 to the container body 20, the operation indicating member 40 is in a first state 100(a) according to the locking operation performed by the latch apparatus 30. When the latch apparatus 30 performs an unlocking operation and does not lock the door body 10 to the container body 20, the operation indicating member 40 is in a second state 100(b) according to the unlocking operation performed by the latch apparatus 30. That is, as shown in FIG. 2B, that the door body 10 is locked and fixed to the container body 20 is the first state 100(a), and that the door body 10 is unlocked and not fixed to the container body 20 is the second state 100(b).

In an embodiment, due to factors such as a large volume and a large weight of an existing semiconductor carrier, to effectively support a weight and stabilize latching, more than one group of latch apparatuses 30 are disposed on the door body 10. In this embodiment, two groups of same latch apparatuses 30 are used as an example, and same structural compositions, operation manners, and functionality are not described in detail again. Certainly, the quantity of the latch apparatuses 30 and positions at which the latch apparatuses 30 are configured on the door body 10 are not limited. The door body 10 further includes a door main body 12 and a sealing plate 14, and the latch apparatus 30 is disposed in an accommodating space S defined by the door main body 12 and the sealing plate 14. The latch apparatus 30 includes: an operating member 31, at least one latch member 32 coupled to the operating member 31, and an unlocking portion 33 and a locking portion 34 that are located on the operating member 31. The sealing plate 14 includes a keyhole 142, and a locking action or an unlocking action is performed by using a mechanical arm or a key to pass through the operating member 31 from the keyhole 142. Operation of the operating member 31 drives the latch member 32 to move linearly, and synchronously enables the unlocking portion 33 to perform unlocking limiting or the locking portion 34 to perform locking limiting. In this way, in the present disclosure, the latch member 32 may be linearly moved to be extended out of the door body 10 or retracted into the door body 10, to lock the door body 10 to or unlock the door body 10 from the container body 20.

Continuing with the foregoing descriptions, to achieve technical functions of enabling the unlocking portion 33 to perform unlocking limiting and enabling the locking portion 34 to perform locking limiting, and to synchronously identify the operation status by using the operation indicating member 40, the latch apparatus 30 further includes an unlocking limit member 35 and a locking limit member 36. The unlocking portion 33 and the unlocking limit member 35 are matched with each other to perform an unlocking function. The locking portion 34 and the locking limit member 36 are matched with each other to perform a locking function. The operation indicating member is preferably disposed on the latch member 32. Certainly, arranged positions and the quantity of the operation indicating members 40 are not limited in the present disclosure. Referring to FIG. 2B, when the latch apparatus 30 is in a locked state, the operation indicating member 40 can be identified as the first (locked) state 100(a) according to a position of the latch member 32, so that a part of the latch member 32 can be extended out of the door body 10 to lock the door body 10 to the container body 20. When the latch apparatus 30 is in an unlocked state, the operation indicating member 40 can be identified as the second (unlocked) state 100(b) according to the position of the latch member 32, so that a part of the latch member 32 can be retracted into the door body 10 to unlock the door body 10 from the container body 20.

Further, as shown in FIG. 3A and FIG. 3B, the sealing plate 14 has a hole 144 for observing the operation indicating member 40. In this embodiment, each group of latch apparatuses 30 includes two latch members 32 on opposite sides. Therefore, four holes 144 are configured on the sealing plate 14 matching the quantity of the latch members 32. Configured positions and the quantity of the holes 144 are not limited in the present disclosure. A state of the operation indicating member 40 may be visually observed by using the hole 144, thereby identifying the operation status of the latch apparatus 30. The operation indicating member 40 has different colors or different patterns, and presents different colors or different patterns in different operation states, to identify the first state 100(a) and the second state 100(b) of the latch apparatus 30. Specifically, the operation indicating member 40 and the latch member 32 are a linked mechanism. For example, the operation indicating member 40 directly or indirectly moves with the latch member 32, so that the hole 144 is displayed differently according to a linear movement stroke of the latch member 32. In this way, an operator can directly view the operation status visually. Certainly, a specific linked mechanism and configuration manner of the operation indicating member 40 and the latch member 32 may be designed according to requirements. It can be known from the foregoing descriptions that in the present disclosure, damage to the door body 10, the latch apparatus 30, and the container body 20, or any one thereof due to improper operation during locking or unlocking when the door body 10 is in the first state 100(a) or the second state 100(b) can be actually prevented. That is, the present disclosure can resolve a conventional problem that whether a door body is in a locked or unlocked state can be determined only from whether the key is rotated 90 degrees from a latch hole, but whether a force is excessively applied or excessively light during operation and that locking is not accurately performed cannot be known. In addition, conventionally, the door body 10 may be separated from the semiconductor container 1 or fall off, or related components may be damaged due to the problem that accurate locking cannot be determined. Through the operation indicating member 40 in an embodiment of the present disclosure, a latched state of the door body 10 can be intuitively and accurately known from an appearance of the door body 10, and identification may alternatively be completed by using an image capture device, an image analysis module, machine vision, or the like, thereby resolving the foregoing conventional problem and effectively protecting the semiconductor container 1 and the door body 10. In addition, in the present disclosure, a clear status indication can be implemented by simply using the operation indicating member 40, and no excessive additional parts or mechanisms are needed. A position of the hole 144 is arranged corresponding to a position of a part of the operation indicating member 40 and the latch member 32, to shorten a required stroke and save space.

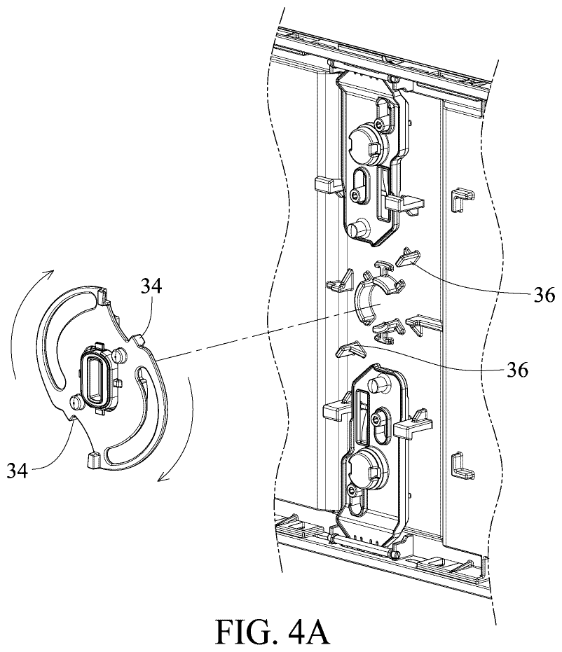

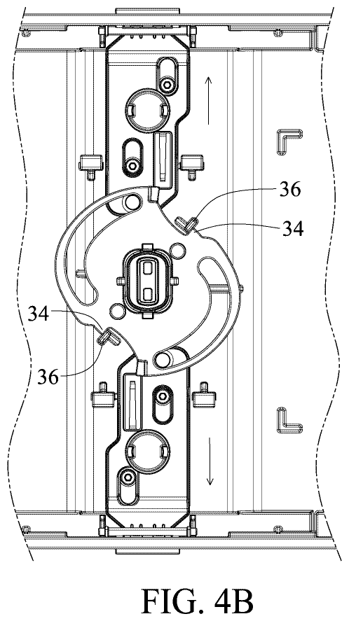

Further, how to implement a function of locking limiting in the present disclosure is further described in detail. Refer to FIG. 2, FIG. 4A, and FIG. 4B together. FIG. 4A and FIG. 4B are schematic diagrams of a locking limit operation according to an embodiment of the present disclosure. A part of the protection apparatus 2 includes an unlocking limit member 35 and a locking limit member 36 of the latch apparatus 30. The function of the locking limit member 36 in this implementation is described first. The operation of the operating member 31 drives the latch member 32 to move linearly, and synchronously drives the locking portion 34 to be paired and moved to the locking limit member 36 to perform locking limiting, so that a part of the latch member 32 is extended out of the door body 10 to lock the door body 10 to the container body 20. In this case, whether the first state 100(a) is presented when the latch apparatus 30 performs the locking operation may be observed or identified through the operation indicating member 40. If the first state 100(a) is presented, it indicates that the locking operation is accurately completed.

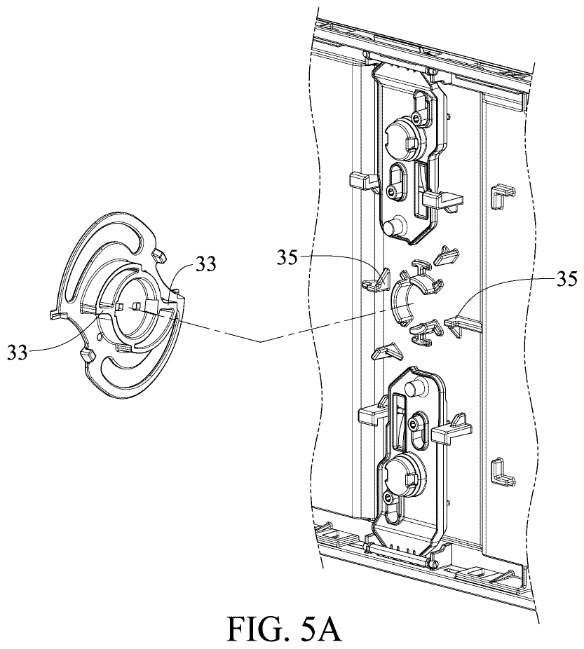

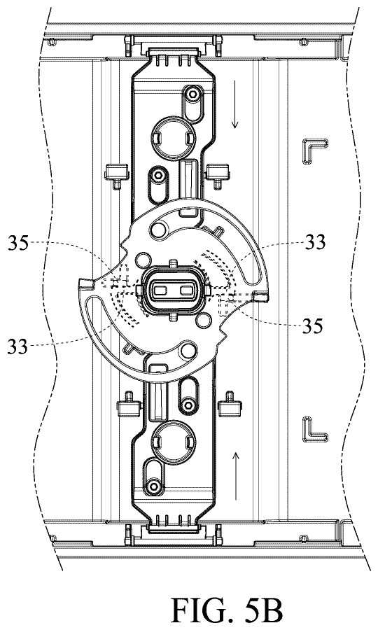

Refer to FIG. 2, FIG. 5A, and FIG. 5B together. FIG. 5A and FIG. 5B are schematic diagrams of an unlocking limit operation according to an embodiment of the present disclosure. A function of the unlocking limit member 35 in this implementation is described herein. The operation of the operating member 31 drives the latch member 32 to move linearly, and synchronously drives the unlocking portion 33 to be paired and moved to the unlocking limit member 35 to perform unlocking limiting, so that a part of the latch member 32 is retracted into the door body 10 and separated and unlocked from the container body 20. In this case, whether the second state 100(b) is presented when the latch apparatus 30 performs the unlocking operation may be observed or identified through the operation indicating member 40. If the second state 100(b) is presented, it indicates that the unlocking operation is accurately completed.

The unlocking limit member 35 and the locking limit member 36 are preferably disposed in the accommodating space S on an inner side of the door main body, to match a specific unlocking portion 33 and locking portion 34 of the operating member 31. The unlocking limit member 35 and the locking limit member 36 are used to limit a range of an actuating stroke of the latch apparatus 30, and limit an actuating position of the latch apparatus 30 when the latch apparatus 30 is switched between the first state 100(a) and the second state 100(b), so that at least a part of components of the latch apparatus 30 stays in an optimal position of the first state 100(a) or the second state 100(b) due to limitation and blocking of the unlocking limit member 35 and the locking limit member 36, without excessively moving, rotating, and displacing the at least a part of the components of the latch apparatus 30 outside the optimal position of the first state 100(a) or the second state 100(b) in a switching process. There is no mechanism interference at the optimal position in the design of the latch apparatus 30, so that the operation is smoother. In this way, in a process of locking or unlocking the door body 10, the protection apparatus 2 can avoid collision, deformation, and damage to the parts of the door body 10 or the latch apparatus 30 on the door body 10 due to an excessive working stroke or an improper operation of the operator. An actuating position and a stroke of a relevant part of the latch apparatus 30 in the door body 10 can be more clearly defined, to ensure that the latch apparatus 30 moves and rotates within a limited range. It should be noted that, configurations such as a quantity and shape of the protection apparatuses are not limited to those shown in FIG. 4 and FIG. 5. Any stroke and position that can block or limit the latch apparatus 30 falls within the protection scope of the present disclosure.

In an embodiment, the unlocking portion 33 and the locking portion 34 may be located at different heights or on different planes on the operating member 31, and the unlocking limit member 35 and the locking limit member 36 disposed on the door main body 12 may also correspondingly have abutting limit surfaces at different heights or on different planes, to match the unlocking portion 33 and the locking portion 34.

In an embodiment, for example, the operating member 31 may have a front surface and a back surface. The unlocking portion 33 configured for position limiting during the unlocking operation may be disposed on the back surface of the operating member 31 (for example, as shown in FIG. 5A), and the locking portion 34 configured for position limiting during the locking operation may be disposed on the front surface of the operating member 31 (for example, as shown in FIG. 4A). In a process of performing the unlocking operation or the locking operation, the unlocking portion 33 and the locking portion 34 are not in friction contact with the unlocking limit member 35 and the locking limit member 36, and are in contact with each other and abut against each other for limiting positions only at an end point of the operation.

In an embodiment, the unlocking limit member 35 and the locking limit member 36 may alternatively be disposed on the sealing plate 14, to reduce parts and features of the door main body 12 and effectively utilize space.

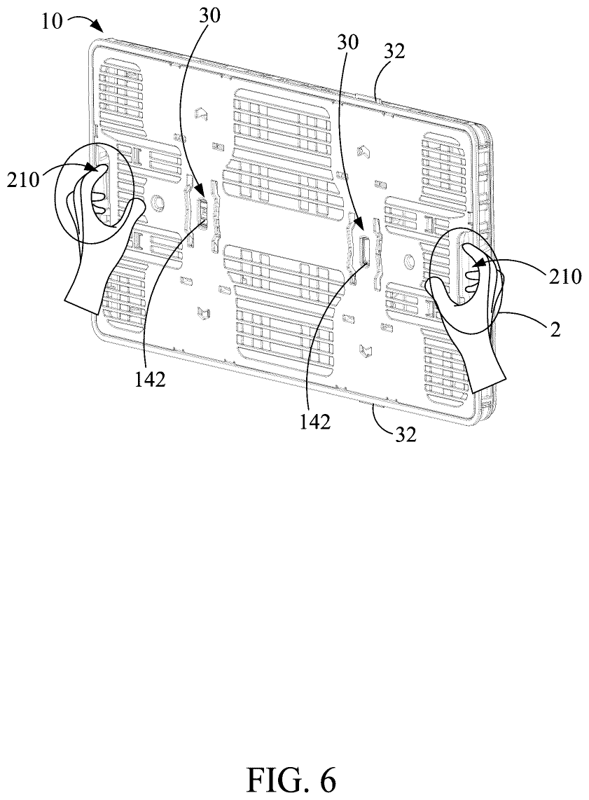

FIG. 6 is a three-dimensional schematic diagram of a door body according to an embodiment of the present disclosure. A part of the protection apparatus 2 includes a picking portion 210. The picking portion 210 is configured to allow an external force to pick the door body 10 when the door body 10 is moved, to prevent, when the door body 10 is moved, a problem of deformation or damage to the door body 10 and/or the latch apparatus 30 due to a force concentratedly applied to the latch apparatus 30 during picking of the door body 10. In an embodiment, at least two picking portions 210 are provided, and are respectively configured on two sides adjacent to the door body 10, for picking the door body 10.

A principle of protecting the door body 10 by the picking portion 210 is described below. For example, descriptions are provided by using the related art as comparison. In the related art, to open the door body 10, the operator uses a key or the like to open and drive the latch apparatus 30 disposed on the door body 10, so that after the latch apparatus 30 is released from a latched state, the operator jointly pulls the key and the door body 10, so that the door body 10 can be forced to be moved and separated from the container body 20, thereby opening the door body 10. However, in the operation manner of the related art, when the operator jointly pulls the key and the door body 10 to open the door body 10, most of the weight of the door body 10 is borne by the key and the keyhole 142. Because the keyhole 142 and the related latch apparatus 30 need to bear the weight of the entire door body 10, it is easy for the keyhole 142 and the related parts of the latch apparatus 30 to be damaged due to compression and deformation by force, and even worse, the door body 10 is damaged.

Through the picking portion 210 of the protection apparatus 2 provided in an embodiment of the present disclosure, when the operator intends to open and remove the door body 10, after the operator inserts the key into the keyhole 142 and releases the locked state of the door body 10, the door body 10 changes to the second state 100(b). The door body 10 can be picked through the picking portion 210 of the protection apparatus 2, so that when the door body 10 undergoes a force and moves, the force is borne by the picking portion 210 of the protection apparatus 2, instead of being borne by the key, the corresponding keyhole 142, and the latch apparatus 30, thereby effectively avoiding a damage caused by a stress concentrated on the latch apparatus 30 when the door body 10 is unlocked, opened, and moved and removed. It should be noted that the use of the protection apparatus 2 and the picking portion 210 thereof is not limited to unlocking and removing the door body 10, and may also be applicable to a process of assembling and locking the door body 10.

In an embodiment, the picking portion 210 is disposed adjacent to the latch apparatus 30. For example, the picking portion 210 is disposed adjacent to the keyhole 142, so that after using the key to unlock the latch apparatus 30 of the door body 10, the operator can directly move a hand with a relatively small stroke to an adjacent picking portion 210 for picking, thereby having good unlocking and picking efficiency.

In an embodiment, two picking portions 210 are provided, and are symmetrically disposed on two sides of the door body 10. In this way, the operator can directly pick the door body 10 efficiently with hands (such as a circle shown in FIG. 6) after unlocking, and stably pick the door body 10. The operator can also pick the door body 10 intuitively.

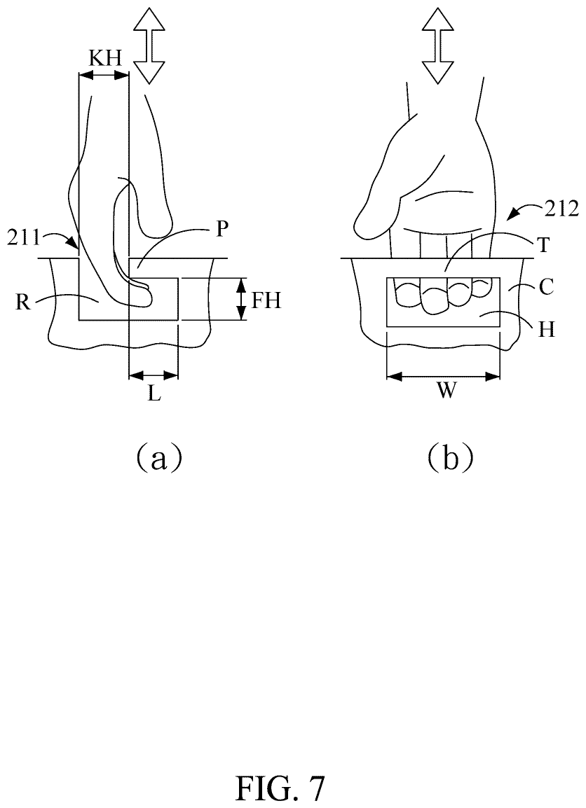

FIG. 7 is a schematic structural diagram of a picking portion of a door body according to an embodiment of the present disclosure. In an embodiment, the picking portion 210 is a picking groove 211, for example, as shown in a part (a) in FIG. 7, so that the hand of the operator partially extends into the picking groove 211 to pick the door body 10. In an embodiment, the picking groove 211 further includes a placing groove R and a holding flange P, so that fingers of the operator can easily extend into and hold the picking groove 211. In an embodiment, the size and specification designs of the picking groove 211 both comply with the SEMI human factors standard, so that general operators can easily and efficiently pick the door body 10. In an embodiment, a finger joint accommodating height KH of the picking groove 211 is at least 28 mm, a finger holding length L is at least 18 mm, and a finger accommodating height FH is at least 22 mm. In an embodiment, the picking portion 210 is a picking handle 212, for example, as shown in a part (b) in FIG. 7, so that the hand of the operator can directly hold the picking handle 212 to pick the door body 10. In an embodiment, the picking handle 212 includes a holding bar T and a connection bar C, so that the fingers of the operator can easily hold the picking handle 212. In an embodiment, the size and specification designs of the picking handle 212 both comply with the SEMI human factor standard, and a finger accommodating width W is at least 91 mm. It should be noted that, the descriptions of picking, holding, and the like in the foregoing embodiments may be completed by the operator by using the hand, or may be completed by a holder such as a robot arm or an automatic machine, and are not limited by the exemplary hand of the operator.

In this way, through a combination of the latch apparatus and the operation indicating member provided by the door body of the semiconductor container of the present disclosure, in a process of opening and closing the door body and locking and unlocking the latch apparatus, whether the door body is locked to the container body is intuitively and clearly determined at any time, thereby avoiding damage caused by separating or falling of the door body due to incorrect force application to the door body. Through arrangement of the latch apparatus and the locking/unlocking limit member, during locking of the door body, damage to the door body or the latch apparatus on the door body caused by an excessive working stroke may alternatively be avoided through the locking/unlocking limit member. In addition, through arrangement of the picking portion of the door body, an external force may alternatively be applied to the picking portion, to avoid damage to fixing mechanisms such as the door body or the latch apparatus caused by excessively concentrated force applied to the door body or the latch apparatus on the door body. Therefore, the latch apparatus, the operation indicating member, and the like provided by the door body in the present disclosure have effects of protecting the door body from being damaged and improving the service life.

The present disclosure has been disclosed in the above with embodiments. However, a person skilled in the art should understand that the embodiments are only used to illustrate the present disclosure, and should not be interpreted as a limitation on the scope of the present disclosure. It should be noted that all variations, substitutions, and combinations equivalent to the embodiments should be considered to be within the scope of the present disclosure. Therefore, the protection scope of the present disclosure shall be based on that defined by the scope of the patent application, and the scope of the attached claims shall be interpreted in the broadest sense to include all modifications, combinations, similar arrangements, and processes.

While the present disclosure has been described by means of specific embodiments, numerous modifications and variations could be made thereto by those skilled in the art without departing from the scope and spirit of the present disclosure set forth in the claims.

What is claimed is:

1. A door body, applicable to a semiconductor container, wherein the door body comprises:
a latch apparatus, disposed on the door body, wherein the latch apparatus is configured to lock the door body to or unlock the door body from the semiconductor container; and
an operation indicating member, disposed on the latch apparatus, wherein the operation indicating member is configured to identify an operation status.

2. The door body according to claim 1, wherein the operation indicating member is in a first state according to a locking operation performed by the latch apparatus, and is in a second state according to an unlocking operation.

3. The door body according to claim 2, wherein the operation indicating member has different colors, to identify the first state or the second state.

4. The door body according to claim 2, wherein the latch apparatus comprises an unlocking limit member and a locking limit member, the latch apparatus is in the first state when the locking operation is performed on the locking limit member, and the latch apparatus is in the second state when the unlocking operation is performed on the unlocking limit member.

5. The door body according to claim 4, wherein the latch apparatus further comprises: an operating member, at least one latch member coupled to the operating member, and an unlocking portion and a locking portion that are located on the operating member, wherein operation of the operating member drives the latch member to move linearly and synchronously drives the unlocking portion and the locking portion, the unlocking portion is paired and moved to the unlocking limit member to perform unlocking limiting, and the locking portion is paired and moved to the locking limit member to perform locking limiting.

6. The door body according to claim 1, wherein the door body further comprises a door main body and a sealing plate, the latch apparatus is disposed in an accommodating space defined by the door main body and the sealing plate, and the sealing plate has a hole for observing the operation indicating member.

7. The door body according to claim 1, wherein the door body further comprises at least two picking portions respectively configured on two sides adjacent to the door body, and the picking portions are provided for picking the door body.

8. A door body, applicable to a semiconductor container, wherein the door body is configured to be combined with the semiconductor container, and the door body comprises:
a latch apparatus, disposed on the door body, wherein the latch apparatus is configured to lock the door body to or unlock the door body from the semiconductor container;
an operation indicating member, disposed on the latch apparatus, wherein the operation indicating member is configured to identify an operation status; and
at least two picking portions, respectively configured on two sides adjacent to the door body, wherein the picking portions are provided for picking the door body.

9. The door body according to claim 8, wherein the picking portion is a picking groove.

10. The door body according to claim 9, wherein the picking groove comprises a placing groove and a holding flange.

11. The door body according to claim 8, wherein the picking portion is a picking handle.
